(19) United States
(12) Patent Application Publication
(10) Pub. No.: US 2026/0247644 A1
(43) Pub. Date: Aug. 20, 2026

(54) TRENCH-TYPE INSULATED GATE BIPOLAR TRANSISTOR AND PREPARATION METHOD THEREOF

(71) Applicant: GlenFly Tech Co., Ltd., Shanghai (CN)

(72) Inventors: Na LI, Shanghai (CN); Tao ZHANG, Shanghai (CN)

(21) Appl. No.: 19/188,440

(22) Filed: Apr. 24, 2025

(30) Foreign Application Priority Data
Feb. 19, 2025 (CN) 202510187802.6

(51) Int. Cl. H10D 12/00; H10D 12/01

(52) U.S. Cl. CPC H10D 12/481; H10D 12/038

(57) ABSTRACT

Trench-type insulated gate bipolar transistor includes substrate, plurality of trench gate structures, oxidation isolation buried layer and plurality of electrodes, substrate includes first body region, second body region, first active region and second active region; second body region is located at upper side of first body region, trench gate structures include first emitter trench gate structure, first active trench gate structure, second active trench gate structure and second emitter trench gate structure arranged in order, oxidation isolation buried layer is located at junction of first body region and second body region, between first active trench gate structure and second active trench gate structure, electrodes include first emitter located between first active trench gate structure and second active trench gate structure. Technical solution of present application is able to reduce turn-off loss and probability of failure caused by heating of device while ensuring low saturation voltage and switching loss.

### CROSS-REFERENCES TO RELATED APPLICATION

The present application claims the priority of Chinese Patent Application No. 2025101878026, filed on Feb. 19, 2025. The contents of the above application are incorporated herein by reference.

### FIELD OF TECHNOLOGY

The present application relates to the technical field of semiconductor, and more specifically, to a trench-type insulated gate bipolar transistor and a preparation method thereof.

### BACKGROUND

An insulated gate bipolar transistor (IGBT) has a plurality of characters including high input impedance, a low forward voltage drop, a fast switching speed and a low loss, having been widely applied in a plurality of fields including new energy, transportation, power grid and industry. These applications often require the IGBT to have a high current and a high breakdown voltage, as long as a low switching loss.

In the prior art, a turn-on loss and a turn-off loss of the IGBT are mutually balanced, which is difficult to be reduced at a same time. However, in an application, for the switching loss of the IGBT, it is the lower, the better. This not only helps to keep a device stable, but also improves both working efficiency and service life of the device.

In the prior art, the IGBT has either a low turn-on loss or a low turn-off loss. For the IGBT having a low turn-on loss, it controls a carrier outflow slow during a turn-on process, thus having a low saturation voltage. However, during a turn-off process, the carrier outflow is still slow. Thus the turn-on loss is low but the turn-off loss ishigh. For the IGBT having a low turn-off loss, during a turn-on process, there are more carriers flowing out through an emitter, thus having a high saturation voltage and a high turn-on loss. During a turn-off process, the carriers being stored are flowing out faster, thus the turn-off loss is smaller. Both types of the IGBT have their own advantages and disadvantages, without being able to guarantee a low saturation voltage, a low turn-on loss and a low turn-off loss at a same time.

### SUMMARY

The technical problem to be solved by the present application is to provide a trench-type insulated gate bipolar transistor and a preparation method thereof, which is able to reduce the turn-off loss while guaranteeing the low saturation voltage and the low turn-on loss, thus reduce a probability of device failure caused by heating, extend a service life of the device, and improve a reliability of the device.

A first aspect of the present application, in an embodiment, provides a trench-type insulated gate bipolar transistor, comprising:
a substrate having a cell region, comprising a first body region of a first conductivity type, a second body region of a second conductivity type, a first active region and a second active region of the first conductivity type; both the first body region and the second body region locating in the cell region, and the second body region locating above the first body region; both the first active region and the second active region locating on a side in the second body region away from the first activeregion;
a plurality of trench gate structures penetrating through the second body region in a first direction until extending into the first body region, comprising a first emitter trench gate structure, a first active trench gate structure, a second active trench gate structure and a second emitter trench gate structure arranged in an order following a second direction; the first active region being located between the first emitter trench gate structure and the first active trench gate structure, the second active region being located between the second active trench gate structure and the second emitter trench gate structure; the first direction being perpendicular to the substrate, the second direction being perpendicular to the first direction;
an oxidation isolation buried layer located at a junction of the first body region and the second body region, between the first active trench gate structure and the second active trench gate structure;
a plurality of electrodes extending into the second body region along the first direction, and protruding out of the second body region, comprising a first active gate, a first emitter and a second active gate, the first active gate penetrating through the first active region and extending into the second body region, the second active gate penetrating through the second active region and extending into the second body region; the first emitter being positioned between the first active trench gate structure and the second active trench gate structure in the second direction.

In an embodiment, the oxidation isolation buried layer has at least a portion locating inside the second body region.

In an embodiment, a length of the oxide isolation buried layer in the second direction is positively related to a doping concentration of the second body region, a first gap is existing between the oxide isolation buried layer and the first active trench gate structure, and a second gap is existing between the oxide isolation buried layer and the second active trench gate structure respectively.

In an embodiment, a projection of the first emitter on the substrate is within a projection of the oxide isolation buried layer on the substrate, and a third gap is existing between the first emitter and the oxide isolation buried layer.

In an embodiment, a material of the oxide isolation buried layer is siliconoxide.

In an embodiment, an upper surface of the first active region, an upper surface of the second active region and an upper surface of the second body region are on a same level.

In an embodiment, the trench-type insulated gate bipolar transistor also comprises a first interlayer dielectric layer located on the side of the second body region away from the first body region, and the plurality of electrodes penetrate through the first interlayer dielectric layer before extending into the second body region;
the substrate further comprises a carrier storage layer, a first field cutoff layer and a first collector region, the carrier storage layer being positioned between the first integration region and the second body region, while the first field cutoff layer being positioned between the first body region and the first collector region.

In an embodiment, the trench-type insulated gate bipolar transistor further comprises a first conductive layer and a second conductive layer;
the first conductive layer is located on a side of the first interlayer dielectric layer away from the second body region, and is electrically connected to the plurality of electrodes;
the second conductive layer is located on a side of the first collector region away from the first field cutoff layer.

A second aspect of the present application, in an embodiment, provides a preparation method for the trench-type insulated gate bipolar transistor stated above, comprising:
providing the substrate of the first conductivity type, applied to providingthe first body region;
implanting oxygen ions into a designated position in the substrate to form an oxygen ion buried layer;
adopting a high-temperature process to treat the oxygen ion buried layer and form the oxide isolation buried layer;
forming the plurality of trench gate structures in the substrate;
adopting an ion implantation process to form the second body region, the first active region and the second active region in the substrate;
forming the first interlayer dielectric layer on the side of the second body region away from the first body region;
adopting an etching process to form a plurality of contact holes, the plurality of contact holes penetrating the first interlayer dielectric layer and extending into the second body region; a plurality of positions of the plurality of contact holes are corresponding to a plurality of positions of the plurality of electrodes in a one-to-onebasis;
depositing a conductive material in the plurality of contact holes to form the plurality of electrodes.

In an embodiment, when the substrate further comprises the carrier storage layer, before the step of depositing the conductive material in the plurality of contact holes to form the plurality of electrodes, further comprising:
implanting doped ions of the first conductivity type into the substrate to form a doped layer;
adopting the high-temperature process to treat the doped layer to form the carrier storage layer; wherein the step of adopting the high-temperature process to process the doped layer to form the carrier storage layer and the step of adopting the high-temperature process to treat the oxygen ion buried layer to form the oxide isolation buried layer belong to a same process.

Compared with the prior art, the present application has the beneficial effect that: since the trench-type insulated gate bipolar transistor comprises not only the substrate, the plurality of trench gate structures and the plurality of electrodes stated above, but also the oxide isolation buried layer is located at the junction of the first body region and the second body region, between the first active trench gate structure and the second active trench gate structure, the first emitter is located between the first active trench gate structure and the second active trench gate structure in the second direction, also since a doping concentration is low around a position of the oxide isolation buried layer, when applying a voltage to the first active trench gate structure and the second active trench gate structure, to turn on the trench-type insulated gate bipolar transistor, it is easy to get inversed and form an electron region around a position of the oxide isolation buried layer, preventing a plurality of holes from flowing out, together with an ability of the oxide isolation buried layer preventing the carriers from flowing out, it is possible to prevent the first emitter between the first active trench gate structure and the second active trench gate structure from pumping out the carriers when the transistor is turned on, thereby maintaining a low saturation voltage and a small turn-on loss. During a process of turning off the transistor, the first active trench gate structure and the second active trench gate structure have no voltage being applied, thus losing the ability of inverting the second body region, the carriers around the position of the oxide isolation buried layer can be pumped out wherefrom by the first emitter between the first active trench gate structure and the second active trench gate structure, thereby accelerating the turning off process and reducing the turn-off loss. In conclusion, the technical solution provided by the present application is able to reduce the turn-off loss of the device while ensuring a low saturation voltage and a small turn-on loss, also reduce the probability of device failure caused by heating, and extend the service life of the device and improve the reliability of the device.

### BRIEF DESCRIPTION OF THE DRAWINGS

FIG. 1 illustrates a schematic structural diagram on a trench-type insulated gate bipolar transistor according to the prior art.

FIG. 2 illustrates a schematic structural diagram on another trench-type insulated gate bipolar transistor according to the prior art.

FIG. 3 illustrates a schematic structural diagram on a trench-type insulated gate bipolar transistor according to an embodiment of the present application;

FIG. 4 illustrates a simulation diagram on the trench-type IGBT shown in FIG. 1 in an on state.

FIG. 5 illustrates a simulation diagram on the trench-type IGBT shown in FIG. 2 in an on state.

FIG. 6 illustrates a simulation diagram on the trench-type IGBT shown in FIG. 3 in an on state.

FIG. 7 illustrates a flow chart on a preparation method of a trench-type insulated gate bipolar transistor according to an embodiment of the present application;

FIG. 8 illustrates a flow chart on a preparation method of a trench-type insulated gate bipolar transistor according to another embodiment of the presentapplication.

Wherein: 31—substrate, 311—first body region, 312—second body region of second conductivity type, 313—first active region, 314—second active region, 315—first field cutoff layer, 316—first collector region, 32—plurality of trench gate structures, 321—first emitter trench gate structure, 322—first active trench gate structure, 323—second active trench gate structure, 324—second emitter trench gate structure, 33—oxidation isolation buried layer, 34—first interlayer dielectric layer, 35—electrode, 351—first active gate, 352—first emitter, 353—second active gate, 36—first conductive layer, 37—second conductive layer

### DESCRIPTION OF THE EMBODIMENTS

Unless otherwise defined, technical or scientific terms used in the present specification and claims shall have the common meanings as understood by those skilled in the art to which the present application belongs. The specific embodiments of the present application will be described below in conjunction with the accompanying drawings. It should be pointed out that in the specific description process of these embodiments, in order to provide a concise and clear description, this specification cannot provide a detailed description of all the features of the actual embodiments. Without departing from the spirit and scope of the present application, those skilled in the art may modify and replace the embodiments of the present application, and the resulting embodiments are also within the scope of protection of the present application.

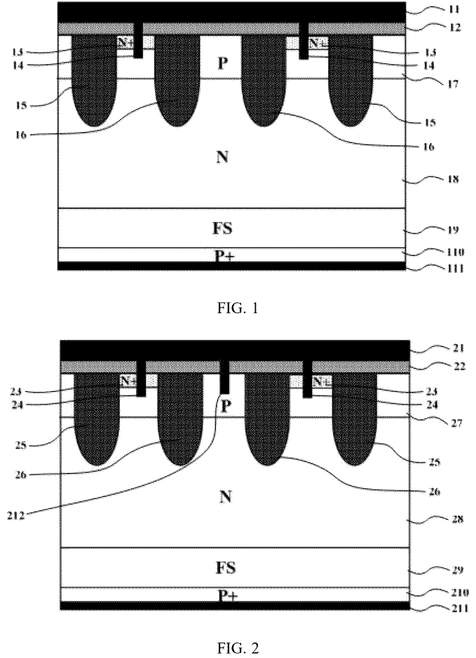

In the prior art, an IGBT shown in FIG. 1 has a low saturation voltage, due to a plurality of carriers flowing out being controlled when it is being turned on, but when it is being turned off, the plurality of carriers flowing out is also slow, thus it has a low turn-on loss, but a high turn-off loss. Wherein the IGBT shown in FIG. 1 comprises a first electrode lead-out layer 11, a second interlayer dielectric layer 12, two third active regions 13, two third active gates 14, two second emitter trench gate structures 15, two second active gate trench gate structures 16, a third body region 17, a fourth body region 18, a second field cutoff layer 19, a second collector region 110 and a first collector 111. A material of both the first electrode lead-out layer 11 and the first collector 111 is a metal, the two third active regions 13 are both N+ type active regions, the third body region 17 is a P-type body region, the fourth body region 18 is an N type body region, and the second collector region 110 is a P+ type collector region.

For an IGBT shown as FIG. 2, if more metals are connected, more carriers will flow out through a second emitter 212 when being turned on, a saturation voltage will be high, and a turn-on loss will also be high; and when being turned off, the carriers being stored will flow out faster, and a turn-off loss will be smaller. The IGBT shown in FIG. 2 comprises a second electrode lead-out layer 21, a third interlayer dielectric layer 22, two fourth active regions 23, two fourth active gates 24, a second emitter 212, two third emitter trench gate structures 25, two third active gate trench gate structures 26, a fifth body region 27, a sixth body region 28, a third field cutoff layer 29, a third collector region 210 and a second collector 211, wherein a material of both the second electrode lead-out layer 21 and the second collector 211 is metal, the two fourth active regions 23 are N+ type active regions, the fifth body region 27 is a P-type body region, the sixth body region 28 is an N type body region, and the third collector region 210 is a P+ type collector region.

Either structure of the two IGBTs stated above has both advantages and disadvantages, but neither can guarantee a low saturation voltage, a low turn-on loss and a low turn-off loss at a same time.

In order to solve the technical problem stated above, according to an embodiment of the present application, a trench-type insulated gate bipolar transistor and a preparation method thereof is provided herein, being able to reduce the turn-off loss of a device while ensuring a low saturation voltage and a small turn-on loss, thus reduce a probability of device failure caused by heating, extend both service life and reliability of the device.

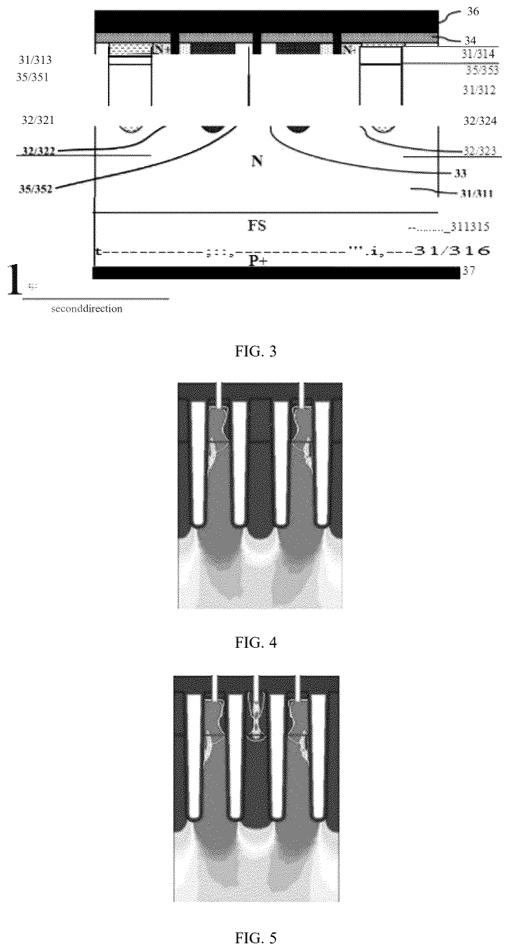

According to an embodiment of the present application, a trench-type insulated gate bipolar transistor is provided, shown as FIG. 3, comprising: a substrate 31, a plurality of trench gate structures 32, an oxidation isolation buried layer 33, a first interlayer dielectric layer 34, a plurality of electrodes 35, a first conductive layer 36 and a second conductive layer 37.

In an embodiment, the substrate 31 comprises a cell region (not shown) and a terminal region (not shown), the terminal region is located at a periphery of the cell region. According to the technical scheme disclosed by the present application, only a structural improvement of the cellular region is involved, thus the terminal region will not be introduced herein.

In an embodiment, a conductivity type of the substrate 31 is, but not limited to, a first conductivity type, such as an N-type. The substrate 31 may be applied to providing a first body region of a first conductivity type, and the first body region may be a drift region.

In an embodiment, shown as FIG. 3, the substrate 31 comprises a first body region 311 of the first conductivity type, a second body region 312 of a second conductivity type, a first active region 313 of the first conductivity type and a second active region 314 of the first conductivity type, a first field cutoff layer 315 and a first collector region 316.

In an embodiment, the first conductivity type is an N type, the second conductivity type is a P type, but not limited thereto.

Shown as FIG. 3, both the first body region 311 and the second body region 312 are locating in the cell region, and the second body region 312 is locating above the first body region 311; both the first active region 313 and the second active region 314 are locating on a side in the second body region 312 away from the first active region. An upper surface of the first active region 313, an upper surface of the second active region 314 and an upper surface of the second body region 312 are on a samelevel.

In order for a convenient expression, it is agreed in the specification that, the first direction is an upward direction in FIG. 3, an upper surface of a component is a surface of the component in downstream of the first direction, and the back surface of the component is a surface in upstream of the first direction.

In an embodiment, the first body region 311 is a drift region, and the second body region 312 is an emission region.

In an embodiment, shown as FIG. 3, the first field cutoff layer 315 is located between the first body region 311 and the first collector region 316. The conductivity type of the first collector region 316 is the second conductivity type. The first collector region 316 is a P+ type collector region.

In an embodiment, the substrate 31 further comprises a carrier storage layer (not shown), and the carrier storage layer is located between the first body region 311 and the second body region 312.

In an embodiment, shown as FIG. 3, a plurality of trench gate structures 32 penetrate through the second body region 312 along the first direction and extend into the first body region 311, while the first direction is perpendicular to the substrate 31.

In an embodiment, shown as FIG. 3, the plurality of trench gate structures 32 comprise a first emitter trench gate structure 321, a first active trench gate structure 322, a second active trench gate structure 323, and a second emitter trench gate structure 324 arranged sequentially in a second direction, while the second direction is perpendicular to the first direction.

In an embodiment, a material of the first emitter trench gate structure 321 and the second emitter trench gate structure 324 comprises a polysilicon and an oxide layer, connecting to a zero potential.

In an embodiment, a material of the first active trench gate structure 322 and the second active trench gate structure 323 comprises a polysilicon and an oxide layer, connecting to a gate pad, applied to controlling a device switch.

Shown as FIG. 3, the first active region 313 is located between the first emitter trench gate structure 321 and the first active trench gate structure 322, and the second active region 314 is located between the second active trench gate structure 323 and the second emitter trench gate structure 324.

Shown as FIG. 3, the oxidation isolation buried layer 33 is located at a junction of the first body region 311 and the second body region 312, between the first active trench gate structure 322 and the second active trench gate structure 323.

In an embodiment, the oxidation isolation buried layer 33 has at least a part locating inside the second body region 312. In an embodiment, the oxidation isolation buried layer 33 has a part located inside the second body region 312, while another part located inside the first body region 311. In another embodiment, the oxidation isolation buried layer 33 is totally located inside the second body region 312.

In an embodiment, a material of the oxidation isolation buried layer 33 is silicon oxide.

In an embodiment, a length of the oxidation isolation buried layer 33 in the second direction is positively correlated with a doping concentration of the second body region 312, that is, the larger the doping concentration of the second body region 312 is, the greater the length of the oxidation isolation buried layer 33 is.

In an embodiment, shown as FIG. 3, between the oxidation isolation buried layer 33 and the first active trench gate structure 322, and between the oxidation isolation buried layer 33 and the second active trench gate structure 323, there is a gap existing respectively.

In one embodiment, shown as FIG. 3, the first interlayer dielectric layer 34 is located on a side of the second body region 312 away from the first body region 311. A material of the first interlayer dielectric layer 34 is silicon oxide, applied to an electrical isolation.

In an embodiment, shown as FIG. 3, a plurality of electrodes 35 penetrate through the first interlayer dielectric layer 34 in the first direction before extending into the second body region 312 and protruding out of the second body region 312.

Shown as FIG. 3, the plurality of electrodes 35 copmrise a first active gate 351, a first emitter 352 and a second active gate 353, the first active gate 351 penetrates through the first active region 313 and extends into the second body region 312, the second active gate 353 penetrates through the second active region 314 and extends into the second body region 312, while the first emitter 352 is located between the first active trench gate structure 322 and the second active trench gate structure 323 in the second direction.

In an embodiment, a material of the electrode 35 is, but not limited to, a metal material, or a plurality of other conductive materials.

In an embodiment, shown as FIG. 3, a projection of the first emitter 352 on the substrate 31 is located inside a projection of the oxidation isolation buried layer 33 on the substrate 31, and there is a gap existing between the first emitter 352 and the oxidation isolation buried layer 33.

In an embodiment, shown as FIG. 3, the first conductive layer 36 is located on a side of the first interlayer dielectric layer 34 away from the second body region 312, and electrically connected to the plurality of electrodes 35. A material of the first conductive layer 36 is a metal, applied to leading out the electrode 35 and electrically connecting to an external device.

In an embodiment, shown as FIG. 3, the second conductive layer 37 is located on a side of the first collector region 316 away from the first field cutoff layer 315. The second conductive layer 37 is a collector. A material of the second conductive layer 37 is a metal.

In the present application, since the oxide isolation buried layer 33 is located at the junction of the first body region 311 and the second body region 312, between the first active trench gate structure and the second active trench gate structure, the first emitter 352 is located between the first active trench gate structure and the second active trench gate structure in the second direction, also since a doping concentration is low around a position of the oxide isolation buried layer 33, when applying a voltage to the first active trench gate structure and the second active trench gate structure, to turn on a trench-type insulated gate bipolar transistor, it is easy to get inversed and form an electron region around a position of the oxide isolation buried layer 33, preventing a plurality of holes from flowing out, together with an ability of the oxide isolation buried layer 33 preventing the carriers from flowing out, it is possible to prevent the first emitter 352 between the first active trench gate structure and the second active trench gate structure from pumping out the carriers when the transistor is turned on, thereby maintaining a low saturation voltage and a small turn-on loss. During a process of turning off the transistor, the first active trench gate structure and the second active trench gate structure have no voltage being applied, thus losing the ability of inverting the second body region 312, the carriers around the position of the oxide isolation buried layer 33 can be pumped out therefrom by the first emitter 352 between the first active trench gate structure and the second active trench gate structure, thereby accelerating the turning off process and reducing the turn-off loss.

An IGBT device is often switched between turn-on and turn-off during an application process, both turn-on and turn-off will lose energy, and generate heat to influence the stability of the device. In addition, a voltage of the device during working is a saturation voltage, the smaller the voltage is, the smaller the energy loss generated during working is, and the less the heat is generated, which is a great advantage for anapplication.

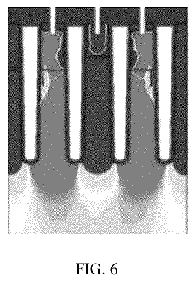

FIG. 4 illustrates a simulation diagram on a conventional IGBT shown in FIG. 1 in an on state, FIG. 5 illustrates a simulation diagram on the trench-type IGBT shown in FIG. 2 in an on state, FIG. 6 illustrates a simulation diagram on the trench-type IGBT shown in FIG. 3 in an on state, wherein red represents more holes, and blue represents less holes.

For a conventional IGBT, if it is trying to reduce the turn-on loss, a low saturation voltage shall be ensured, then it shall be ensured that when the device is in an on state, a plurality of carriers therein will not be pumped out by an electrode; however, it is exactly opposite to lower the turn-off loss, which requires the carriers therein to be pumped out rapidly. Thus when increasing the electrodes in the cell, it reduces the turn-off loss, but at a same time increases the saturation voltage, the heat generated during working and the energy loss when being turned on. However, if the electrodes are not increased, it is possible to guarantee a low saturation voltage and a low turn-on loss, but not able to reduce the turn-off loss, which is very unfavorable for a high-frequency application.

The IGBT provided by the present application has an advantage that, when the device is being turned on, the first active trench gate structure and the second active trench gate structure have an inversion effect, exhausting the P-type region on the surface thereof, together with the oxidation isolation buried layer 33, it is possible to prevent the holes from being pumped out by the first emitter 352 when the device is conducted, so as to keep the low saturation voltage and a small turn-on loss. While the device is being turned off, the first active trench gate structure and the second active trench gate structure have no the inversion effect, not being able to exhaust the P-type region on the surface thereof, thus not being able to form a barrier to keep the holes being inside the device, thus when the device is being turned off, the first emitter 352 will pump out the holes, so as to reduce the turn-off loss of the device.

All above, the IGBT provided by the present application, is able to reduce the turn-off loss of the device while ensuring a low saturation voltage and a small turn-on loss, also reduce the probability of device failure caused by heating, and extend the service life of the device and improve the reliability of the device, which facilitates an application of the device.

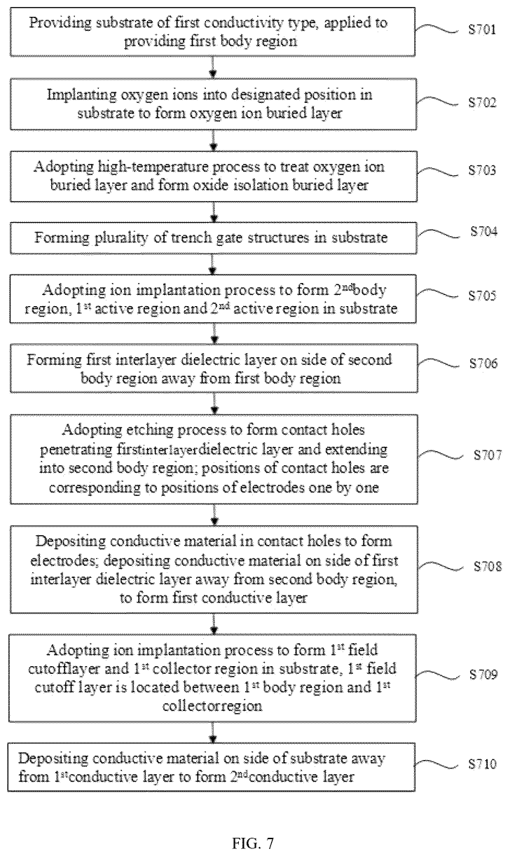

The present application further provides a preparation method for the trench-type insulated gate bipolar transistor. In an embodiment, the preparation method is applied to preparing a trench-type insulated gate bipolar transistor without a carrier storage layer. Shown as FIG. 7, the trench-type insulated gate bipolar transistor comprises a plurality of following steps S701~S710:
Step S701, providing the substrate of the first conductivity type, applied to providing the first body region.

In the present step, it is providing a substrate 31 of the first conductivity type, such as a substrate 31 of an N-type, the substrate 31 is applied to providing the first body region 311, and the first body region 311 may be a drift region.
Step S702, implanting oxygen ions into a designated position in the substrate to form the oxygen ion buried layer.

In the present step, it is possible to adopt a first mask plate to achieve implanting a plurality of oxygen ions into a designed position with a high energy in the substrate 31, to form the oxygen ion buried layer, the first mask plate is applied to limiting an ion implantation region.
Step S703, adopting a high-temperature process to treat the oxygen ion buried layer before forming the oxide isolation buried layer.

In the present step, it adopts a high-temperature process to perform a high-temperature annealing on an intermediate structure prepared in the step S702, so as to forms the oxidation isolation buried layer 33 from the oxygen ion buried layer.
Step S704, forming the plurality of trench gate structures in the substrate.

In the present step, it is possible to adopt an etching process to form a plurality of trenches in the substrate 31, before depositing or growing an oxide layer in the plurality of trenches to form a gate oxide layer, followed by depositing polycrystalline silicon into the trenches to form the plurality of trench gate structures.
Step S705, adopting an ion implantation process to form the second body region, the first active region and the second active region in the substrate 31.

In the present step, it is possible to adopt the ion implantation process to implant doped ions of the second conductivity type into the substrate 31, to form the second body region 312 in the substrate 31. The doped ions of the second conductivity type may be, but not limited to, boron ions. The step of preparing the second body region 312 may be ahead of the step S 704.

After finishing the step of preparing the second body region 312, it further adopts a second mask plate to implant a plurality of doped ions of the first conductive type into an upper surface of the substrate 31, to form the first active region 313 and the second active region 314 in the substrate 31. The second mask plate is applied to defining a plurality of shapes of the first active region 313 and the second active region 314. The doped ions of the first conductivity type may be, but not limited to, phosphorusions.
Step S706, forming the first interlayer dielectric layer on the side of the second body region 312 away from the first body region 311.

In the present step, it forms the first interlayer dielectric layer 34 on the side of the second body region 312 away from the first body region 311, the first interlayer dielectric layer 34 may be silicon oxide, and it is possible to adopt a deposition process to prepare the first interlayer dielectric layer 34.
Step S707, adopting an etching process to form a plurality of contact holes, the plurality of contact holes penetrating the first interlayer dielectric layer 34 and extending into the second body region 312; a plurality of positions of the plurality of contact holes are corresponding to a plurality of positions of the plurality of electrodes in a one-to-one basis.

In the present step, it is possible to adopt the etching process to etch a first interlayer dielectric layer 34 prepared in the step S706 to form the plurality of contact holes, the plurality of contact holes penetrating the first interlayer dielectric layer 34 and extending into the second body region 312; the plurality of positions of the plurality of contact holes are corresponding to the plurality of positions of the plurality of electrodes 35 in a one-to-one basis.
Step S708, depositing a conductive material in the plurality of contact holes to form the plurality of electrodes 35, and depositing a conductive material on a side of the first interlayer dielectric layer 34 away from the second body region 312, to form the first conductive layer 36.

In the present step, it deposits the conductive material in the plurality of contact holes to form the plurality of electrodes 35, and depositing the conductive material on a side of the first interlayer dielectric layer 34 away from the second body region 312, to form the first conductive layer 36. The conductive material may be, but not limited to, a metal.
Step S709, adopting an ion implantation process to form a first field cutoff layer 315 and a first collector region 316 in the substrate 31, the first field cutoff layer 315 is located between the first body region 311 and the first collector region 316.

In the present step, it is possible to implant a plurality of doped ions of a second conductivity type on a back surface of the substrate 31, to form the first collector region 316. The doped ions of the second conductivity type may be, but not limited to, boron ions.

Then implant a plurality of doped ions of the first conductivity type on the back surface of the substrate 31, to form the first field cutoff layer 315. The doped ions of the first conductivity type may be, but not limited to, Hydrogen ions or Phosphorusions.
Step S710, depositing a conductive material on the side of the substrate away from the first conductive layer 36 to form the second conductive layer 37.

In the present step, it is possible to adopt a deposition process to deposit the conductive material on the side of the substrate away from the first conductive layer 36, to form the second conductive layer 37. The conductive material may be a metal.

In the present embodiment, it adopts the first mask plate to achieve positioning and implanting the oxygen ions with high energy, and adopts the high-temperature annealing, to achieve forming the silicon oxide in the region where the oxygen ion buried layer is located, that is, the oxidation isolation buried layer 33. And the high-temperature annealing is a mature process, having a simple preparation process.

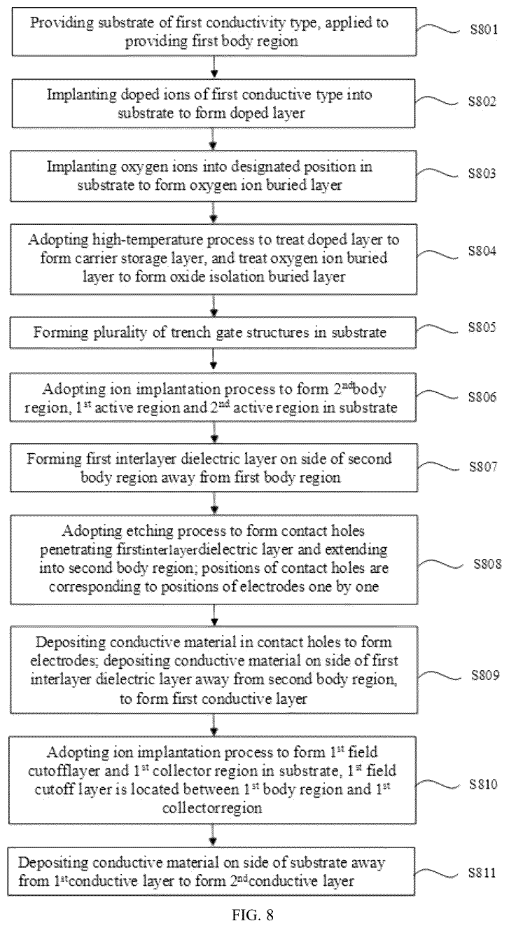

Another embodiment of the present application further provides a preparation method for the trench-type insulated gate bipolar transistor. Different to the embodiment stated above, the preparation method of the present embodiment is applied to preparing a trench-type insulated gate bipolar transistor comprising a carrier storage layer. Shown as FIG. 8, the trench-type insulated gate bipolar transistor comprises a plurality of following steps S801~S811:
Step S801, providing the substrate of the first conductivity type, applied to providing the first body region.

The present step is similar to the step S701 stated above, no more repeatingherein.
Step S802, implanting doped ions of the first conductive type into the substrate to form a doped layer

In the present step, it adopts an ion process to implant doped ions of the first conductive type into the substrate 31, and forms the doped layer. The doped ions of the first conductive type may be, but not limited to, Phosphorus ions.
Step S803, implanting oxygen ions into a designated position in the substrate to form the oxygen ion buried layer.

The present step is similar to the step S702 stated above, no more repeatingherein.
Step S804, adopting a high-temperature process to treat the doped layer before forming the carrier storage layer, and treat the oxygen ion buried layer before forming the oxide isolation buried layer 33.

In the present step, adopting the high-temperature process to treat the doped layer before forming the carrier storage layer, and adopting the high-temperature process to treat the oxygen ion buried layer before forming the oxide isolation buried layer 33, belong to a same process. It is possible to apply an original thermal process in the preparation process for IGBT to the high-temperature annealing process, without requiring any additional processes, which is simple to prepare.
Step S805, forming the plurality of trench gate structures in the substrate 31.

The present step is similar to the step S704 stated above, no more repeatingherein.
Step S806, adopting an ion implantation process to form the second body region, the first active region and the second active region in the substrate 31.

The present step is similar to the step S705 stated above, no more repeatingherein.
Step S807, forming the first interlayer dielectric layer on the side of the second body region 312 away from the first body region 311.

The present step is similar to the step S706 stated above, no more repeatingherein.
Step S808, adopting an etching process to form a plurality of contact holes, the plurality of contact holes penetrating the first interlayer dielectric layer 34 and extending into the second body region 312; a plurality of positions of the plurality of contact holes are corresponding to a plurality of positions of the plurality of electrodes in a one-to-one basis.

The present step is similar to the step S707 stated above, no more repeatingherein.
Step S809, depositing a conductive material in the plurality of contact holes to form the plurality of electrodes 35, and depositing a conductive material on the side of the first interlayer dielectric layer 34 away from the second body region 312, to form the first conductive layer 36.

The present step is similar to the step S708 stated above, no more repeatingherein.
Step S810, adopting an ion implantation process to form a first field cutoff layer 315 and a first collector region 316 in the substrate 31, the first field cutoff layer 315 is located between the first body region 311 and the first collector region 316.

The present step is similar to the step S709 stated above, no more repeatingherein.
Step S811, depositing a conductive material on the side of the substrate away from the first conductive layer 36 to form the second conductive layer 37.

The present step is similar to the step S710 stated above, no more repeatingherein.

In the present embodiment, it adopts the first mask plate to achieve positioning and implanting the oxygen ions with high energy, and adopts the high-temperature annealing to implement forming the silicon oxide in the region where the oxygen ion buried layer is located, that is, the oxidation isolation buried layer 33. And it is possible to apply an original thermal process in the preparation process for IGBT to the high-temperature annealing process, without requiring any additional processes, which is simple to prepare.

In the present application, the terms “first” and “second” are for description purposes only and are not to be construed as indicating or implying relative importance. The term “a plurality of” refers to two or more, unless otherwise expressly defined.

While the embodiments of the present application have been described in detail, it will be apparent to those skilled in the art that various modifications and changes can be made to the embodiments. However, it is to be understood that such modifications and variations are within the scope and spirit of the present application as described in the appended claims. Furthermore, the present application described herein is susceptible to other embodiments and may be embodied or carried out in various ways.

What is claimed is:

1. A trench-type insulated gate bipolar transistor, comprising:
a substrate having a cell region, comprising a first body region of a first conductivity type, a second body region of a second conductivity type, a first active region and a second active region of the first conductivity type; both the first body region and the second body region locating in the cell region, and the second body region locating above the first body region; both the first active region and the second active region locating on a side in the second body region away from the first active region;
a plurality of trench gate structures penetrating through the second body region in a first direction until extending into the first body region, comprising a first emitter trench gate structure, a first active trench gate structure, a second active trench gate structure and a second emitter trench gate structure arranged in an order following a second direction; the first active region being located between the first emitter trench gate structure and the first active trench gate structure, the second active region being located between the second active trench gate structure and the second emitter trench gate structure; the first direction being perpendicular to the substrate, the second direction being perpendicular to the first direction;
an oxidation isolation buried layer located at a junction of the first body region and the second body region, between the first active trench gate structure and the second active trench gate structure;
a plurality of electrodes extending into the second body region along the first direction, and protruding out of the second body region, comprising a first active gate, a first emitter and a second active gate, the first active gate penetrating through the first active region and extending into the second body region, the second active gate penetrating through the second active region and extending into the second body region; the first emitter being positioned between the first active trench gate structure and the second active trench gate structure in the second direction.

2. The trench-type insulated gate bipolar transistor according to claim 1, wherein the oxidation isolation buried layer has at least a portion locating inside the second bodyregion.

3. The trench-type insulated gate bipolar transistor according to claim 1, wherein the oxide isolation buried layer has a length in the second direction positively related to a doping concentration of the second body region, a first gap is existing between the oxide isolation buried layer and the first active trench gate structure, and a second gap is existing between the oxide isolation buried layer and the second active trench gate structure respectively.

4. The trench-type insulated gate bipolar transistor according to claim 1, wherein a projection of the first emitter on the substrate is within a projection of the oxide isolation buried layer on the substrate, and a third gap is existing between the first emitter and the oxide isolation buried layer.

5. The trench-type insulated gate bipolar transistor according to claim 1, wherein a material of the oxide isolation buried layer is silicon oxide.

6. The trench-type insulated gate bipolar transistor according to claim 1, wherein an upper surface of the first active region, an upper surface of the second active region and an upper surface of the second body region are on a same level.

7. The trench-type insulated gate bipolar transistor according to claim 1, further comprising a first interlayer dielectric layer located on the side of the second body region away from the first body region, and the plurality of electrodes penetrating through the first interlayer dielectric layer before extending into the second body region;
the substrate further comprising a carrier storage layer, a first field cutoff layer and a first collector region, the carrier storage layer being positioned between the first integration region and the second body region, while the first field cutoff layer being positioned between the first body region and the first collector region.

8. The trench-type insulated gate bipolar transistor according to claim 7, further comprising a first conductive layer and a second conductive layer;
the first conductive layer is located on a side of the first interlayer dielectric layer away from the second body region, and is electrically connected to the plurality ofelectrodes;
the second conductive layer is located on a side of the first collector region away from the first field cutoff layer.

9. A preparation method for the trench-type insulated gate bipolar transistor according to claim 1, comprising:
providing the substrate of the first conductivity type, applied to providing the first body region;
implanting oxygen ions into a designated position in the substrate to form theoxygen ion buried layer;
adopting a high-temperature process to treat the oxygen ion buried layer and form the oxide isolation buried layer;
forming the plurality of trench gate structures in the substrate;
adopting an ion implantation process to form the second body region, the first active region and the second active region in the substrate;
forming the first interlayer dielectric layer on the side of the second body region away from the first body region;
adopting an etching process to form a plurality of contact holes, the plurality of contact holes penetrating the first interlayer dielectric layer and extending into the second body region; a plurality of positions of the plurality of contact holes are corresponding to a plurality of positions of the plurality of electrodes in a one-to-onebasis;
depositing a conductive material in the plurality of contact holes to form the plurality of electrodes.

10. The preparation method according to claim 9, wherein when the substrate further comprises a carrier storage layer, before the step of depositing the conductive material in the plurality of contact holes to form the plurality of electrodes, further comprising:
implanting doped ions of the first conductivity type into the substrate to form the doped layer;
adopting the high-temperature process to treat the doped layer to form the carrier storage layer; wherein the step of adopting the high-temperature process to process the doped layer to form the carrier storage layer and the step of adopting the high-temperature process to treat the oxygen ion buried layer to form the oxide isolation buried layer belong to a same process.

11. The preparation method according to claim 9, wherein the oxidation isolation buried layer has at least a portion locating inside the second body region.

12. The preparation method according to claim 11, wherein when the substrate further comprises a carrier storage layer, before the step of depositing the conductive material in the plurality of contact holes to form the plurality of electrodes, furthercomprising:
implanting doped ions of the first conductivity type into the substrate to form the doped layer;
adopting the high-temperature process to treat the doped layer to form the carrier storage layer; wherein the step of adopting the high-temperature process to process the doped layer to form the carrier storage layer and the step of adopting the high-temperature process to treat the oxygen ion buried layer to form the oxide isolation buried layer belong to a same process.

13. The preparation method according to claim 9, wherein the oxide isolation buried layer has a length in the second direction positively related to a doping concentration of the second body region, a first gap is existing between the oxide isolation buried layer and the first active trench gate structure, and a second gap is existing between the oxide isolation buried layer and the second active trench gate structure respectively.

14. The preparation method according to claim 13, wherein when the substrate further comprises a carrier storage layer, before the step of depositing the conductive material in the plurality of contact holes to form the plurality of electrodes, furthercomprising:
implanting doped ions of the first conductivity type into the substrate to form the doped layer;
adopting the high-temperature process to treat the doped layer to form the carrier storage layer; wherein the step of adopting the high-temperature process to process the doped layer to form the carrier storage layer and the step of adopting the high-temperature process to treat the oxygen ion buried layer to form the oxide isolation buried layer belong to a same process.

15. The preparation method according to claim 9, wherein a projection of the first emitter on the substrate is within a projection of the oxide isolation buried layer on the substrate, and a third gap is existing between the first emitter and the oxide isolation buried layer.

16. The preparation method according to claim 15, wherein when the substrate further comprises a carrier storage layer, before the step of depositing the conductive material in the plurality of contact holes to form the plurality of electrodes, furthercomprising:
implanting doped ions of the first conductivity type into the substrate to form the doped layer;
adopting the high-temperature process to treat the doped layer to form the carrier storage layer; wherein the step of adopting the high-temperature process to process the doped layer to form the carrier storage layer and the step of adopting the high-temperature process to treat the oxygen ion buried layer to form the oxide isolation buried layer belong to a same process.

17. The preparation method according to claim 9, wherein a material of the oxide isolation buried layer is silicon oxide.

18. The preparation method according to claim 9, wherein an upper surface of the first active region, an upper surface of the second active region and an upper surface of the second body region are on a same level.

19. The preparation method according to claim 9, wherein further comprising a first interlayer dielectric layer located on the side of the second body region away from the first body region, and the plurality of electrodes penetrating through the first interlayer dielectric layer before extending into the second body region;
the substrate further comprising a carrier storage layer, a first field cutoff layer and a first collector region, the carrier storage layer being positioned between the first integration region and the second body region, while the first field cutoff layer being positioned between the first body region and the first collector region.

20. The preparation method according to claim 9, wherein further comprising a first conductive layer and a second conductive layer;
the first conductive layer is located on a side of the first interlayer dielectric layer away from the second body region, and is electrically connected to the plurality ofelectrodes;
the second conductive layer is located on a side of the first collector region away from the first field cutoff layer.
